(19) United States
(12) Patent Application Publication
(10) Pub. No.: US 2025/0386605 A1
(43) Pub. Date: Dec. 18, 2025

(54) ELECTRONIC DEVICE

(71) Applicant: Innolux Corporation, Miaoli County (TW)

(72) Inventors: Yuko Furui, Miaoli County (TW); Hidetoshi Watanabe, Miaoli County (TW); Akihiro Iwatsu, Miaoli County (TW); Shuji Hagino, Miaoli County (TW)

(73) Assignee: Innolux Corporation, Miaoli County (TW)

(21) Appl. No.: 18/741,819

(22) Filed: Jun. 13, 2024

(51) Int. Cl. H01L 27/146

(52) U.S. Cl. CPC H10F 39/8037; H10F 39/811

(57) ABSTRACT

An electronic device is provided. The electronic device includes a sensing pixel. The sensing pixel includes a photosensitive element, a first transistor, a second transistor, and a third transistor. A control terminal of the first transistor is electrically connected to a read signal line. A control terminal of the second transistor is electrically connected to the photosensitive element. A first terminal of the second transistor is electrically connected to a first voltage. A second terminal of the second transistor is electrically connected to a first terminal of the first transistor. A third terminal of the second transistor is electrically connected to a second voltage. A first terminal of the third transistor is electrically connected to a reset voltage. A second terminal of the third transistor is electrically connected to the photosensitive element. A control terminal of the third transistor is electrically connected to a reset signal line.

### BACKGROUND

### Technical Field

The disclosure relates a device; particularly, the disclosure relates to an electronic device.

### Description of Related Art

For a conventional active pixel sensor, during a read-out period, due to a kink effect may occur in a transistor of a source follower amplifier or a current source, therefore the data signal of the sensing result may have unexpected voltage variation, so as to cause distortion of the sensing results read by the back-end circuit.

### SUMMARY

The electronic device of the disclosure includes a sensing pixel. The sensing pixel includes a photosensitive element, a first transistor, a second transistor, and a third transistor. The first transistor includes a first terminal, a second terminal, and a control terminal. The control terminal of the first transistor is electrically connected to a read signal line. The second terminal of the first transistor is electrically connected to a data line. The second transistor includes a first terminal, a second terminal, a third terminal, and a control terminal. The control terminal of the second transistor is electrically connected to the photosensitive element. The first terminal of the second transistor is electrically connected to a first voltage. The second terminal of the second transistor is electrically connected to the first terminal of the first transistor. The third terminal of the second transistor is electrically connected to a second voltage. The third transistor includes a first terminal, a second terminal, and a control terminal. The first terminal of the third transistor is electrically connected to a reset voltage. The second terminal of the third transistor is electrically connected to the photosensitive element. The control terminal of the third transistor is electrically connected to a reset signal line.

The electronic device of the disclosure includes a current source circuit. The current source circuit includes an active load transistor. The active load transistor includes a first terminal, a second terminal, and a third terminal, and a control terminal. The first terminal of the active load transistor is electrically connected to a sensing pixel through a data line. The second terminal of the active load transistor is electrically connected to a third voltage. The third terminal of the active load transistor is electrically connected to a fourth voltage.

Based on the above, according to the electronic device of the disclosure, the electronic device can provide stable circuit operation.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a schematic diagram of an electronic device according to an embodiment of the disclosure.

FIG. 2A is a schematic diagram of a sensing pixel according to an embodiment of the disclosure.

FIG. 2B is a timing diagram of the sensing pixel according to an embodiment of the disclosure.

FIG. 3 is a structural cross-sectional view of a transistor according to an embodiment of the disclosure.

FIG. 4 is a schematic diagram of current-voltage (I-V) characteristics of a transistor according to an embodiment of the disclosure.

FIG. 5 is a schematic diagram of a sensing pixel according to another embodiment of the disclosure.

FIG. 6 is a structural cross-sectional view of a transistor according to another embodiment of the disclosure.

FIG. 7 is a schematic diagram of a current source circuit according to an embodiment of the disclosure.

FIG. 8 is a schematic diagram of a current source circuit according to another embodiment of the disclosure.

### DESCRIPTION OF THE EMBODIMENTS

Reference will now be made in detail to the exemplary embodiments of the disclosure, examples of which are illustrated in the accompanying drawings. Whenever possible, the same reference numbers are used in the drawings and the description to refer to the same or like components.

Certain terms are used throughout the specification and appended claims of the disclosure to refer to specific components. Those skilled in the art should understand that electronic device manufacturers may refer to the same components by different names. This article does not intend to distinguish those components with the same function but different names. In the following description and rights request, the words such as “comprise” and “include” are open-ended terms, and should be explained as “including but not limited to . . . ”.

The term “electrically connect (or couple)” used throughout the whole specification of the present application (including the appended claims) may refer to any direct or indirect connection means. For example, if the text describes that a first device is coupled (or connected) to a second device, it should be interpreted that the first device may be directly connected to the second device, or the first device may be indirectly connected through other devices or certain connection means to be connected to the second device. The terms “first”, “second”, and similar terms mentioned throughout the whole specification of the present application (including the appended claims) are merely used to name discrete elements or to differentiate among different embodiments or ranges. Therefore, the terms should not be regarded as limiting an upper limit or a lower limit of the quantity of the elements and should not be used to limit the arrangement sequence of elements. In addition, wherever possible, elements/components/steps using the same reference numerals in the drawings and the embodiments represent the same or similar parts. Reference may be mutually made to related descriptions of elements/components/steps using the same reference numerals or using the same terms in different embodiments.

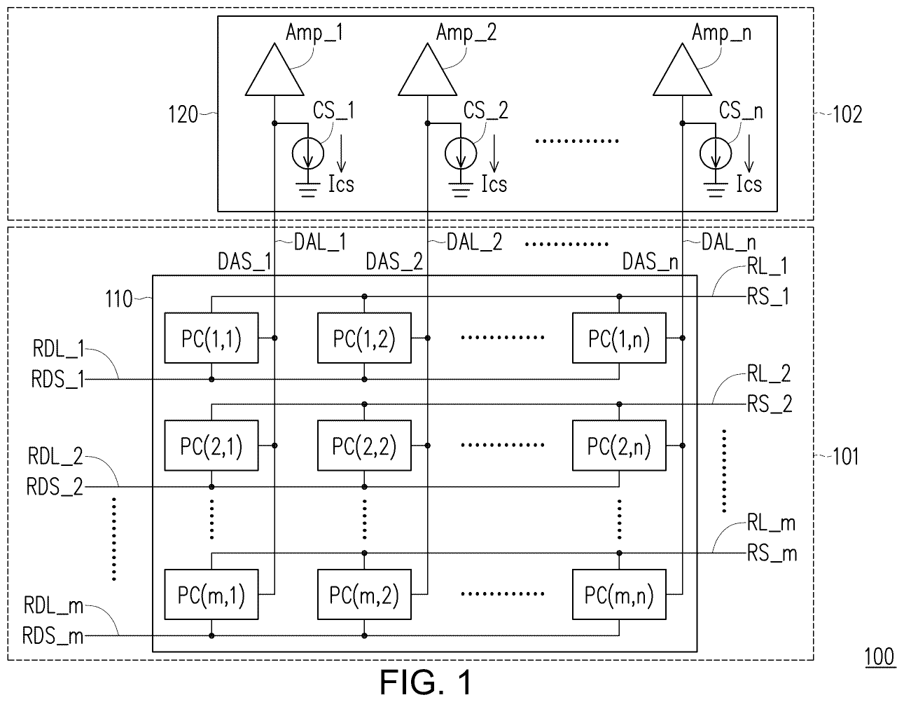

FIG. 1 is a schematic diagram of an electronic device according to an embodiment of the disclosure. Referring to FIG. 1, the electronic device 100 includes a pixel array 110 and a peripheral circuit 120. In the embodiment of the disclosure, the pixel array 110 includes a plurality of sensing pixels PC(1,1) to PC(m,n) arranged in an array, where m and n are positive integers. Each row of the sensing pixels PC(1,1) to PC(m,n) is electrically connected to a corresponding one of a plurality of read signal lines RDL_1 to RDL_m to receive a corresponding one of a plurality of read signals RDS_1 to RDS_m. Each row of the sensing pixels PC(1,1) to PC(m,n) is further electrically connected to a corresponding one of a plurality of reset signal lines RL_1 to RL_m to receive a corresponding one of a plurality of reset signals RS_1 to RS_m. Each column of the sensing pixels PC(1,1) to PC(m,n) is electrically connected to a corresponding one of a plurality of data lines DAL_1 to DAL_n to output a corresponding one of a plurality of data signals DAS_1 to DAS_n.

In the embodiment of the disclosure, the peripheral circuit 120 includes a plurality of amplifier circuits Amp_1 to Amp_n and a plurality of current source circuits CS_1 to CS_n. Each of the amplifier circuits Amp_1 to Amp_n is electrically connected to a corresponding one of the data lines DAL_1 to DAL_n to read out a corresponding one of the data signals DAS_1 to DAS_n. Each of the current source circuits CS_1 to CS_n is electrically connected to a corresponding one of the data lines DAL_1 to DAL_n to supply a constant current.

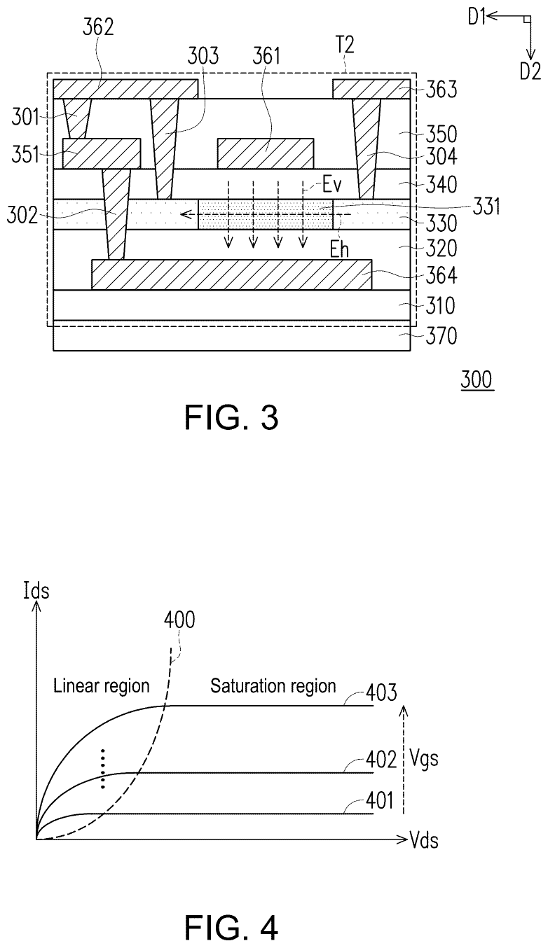

In the embodiment of the disclosure, the electronic device 100 may be an image sensing device, such as a voltage-programmed active pixel sensor (APS). In the embodiment of the disclosure, the image sensing device may be, for example, an X-ray image sensor, an invisible light image sensor, a fingerprint sensor, or a photo sensor. In some embodiments, the sensing pixels PC(1,1) to PC(m,n) may be configured to sense X-ray, invisible light, or visible light. In the embodiment of the disclosure, the pixel array 110 and the peripheral circuit 120 may be disposed on the same substrate (e.g. glass substrate, substrate 370 as shown in FIG. 3, or substrate 670 as shown in FIG. 6), but the disclosure is not limited thereto. In the embodiment of the disclosure, the pixel array 110 may be disposed in an active area 101 of a substrate, and the peripheral circuit 120 may be disposed in a peripheral area 102 of the substrate. In some embodiments, the sensing pixel and the current source circuit can be disposed on the same substrate. The substrate 370 can include an active area 101 and a peripheral area 102 adjacent to the active area 101. The sensing pixel can be disposed on the substrate in the active area 101, and the current source circuit can be disposed on the substrate in the peripheral area 102.

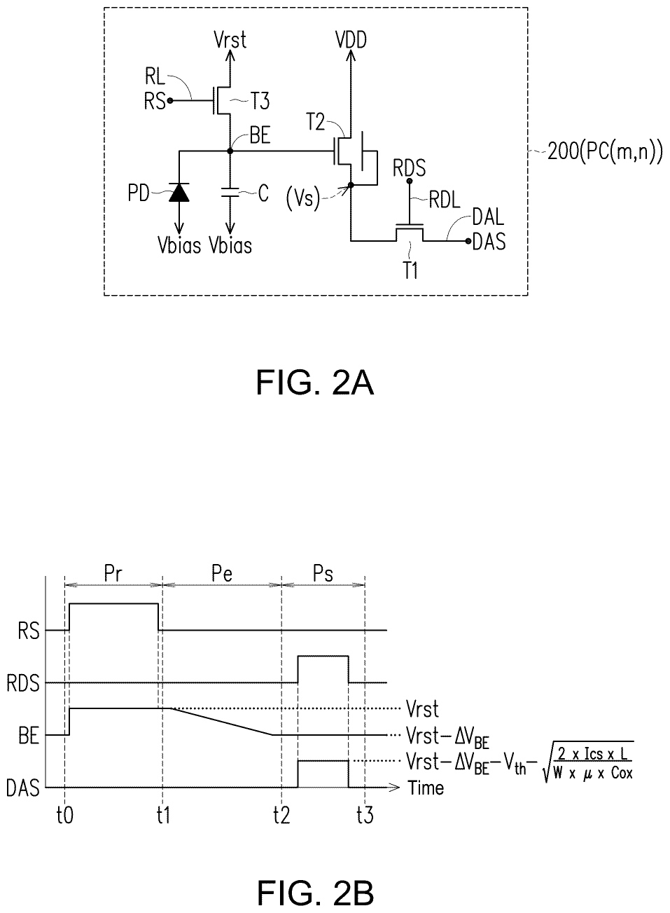

FIG. 2A is a schematic diagram of a sensing pixel according to an embodiment of the disclosure. Referring to FIG. 2A, the circuit architecture of each of the sensing pixels PC(1,1) to PC(m,n) of FIG. 1 may be implemented as the circuit architecture of a sensing pixel 200 of FIG. 2A. In the embodiment of the disclosure, the sensing pixel 200 includes a photosensitive element PD, a capacitor C, a first transistor T1, a second transistor T2, and a third transistor T3. The first transistor T1 includes a first terminal, a second terminal, and a control terminal. The control terminal of the first transistor T1 is electrically connected to a read signal line RDL to receive a read control signal RDS. The first terminal of the first transistor T1 is electrically connected to the second transistor T2. The second terminal of the first transistor T1 is electrically connected to a data line DAL to output a data signal DAS. The second transistor T2 includes a first terminal, a second terminal, a third terminal, and a control terminal. The control terminal of the second transistor T2 is electrically connected to the photosensitive element PD via a node BE. The first terminal of the second transistor T2 is electrically connected to a first voltage VDD (i.e. operation voltage). The second terminal of the second transistor T2 is electrically connected to the first terminal of the first transistor T1. The second terminal of the second transistor T2 has a second voltage Vs. The third terminal of the second transistor T2 is electrically connected to the second terminal of the second transistor T2 to receive the second voltage Vs. The third transistor T3 includes a first terminal, a second terminal, and a control terminal. The first terminal of the third transistor T3 is electrically connected to a reset voltage Vrst. The second terminal of the third transistor T3 is electrically connected to the photosensitive element PD via the node BE. The control terminal of the third transistor T3 is electrically connected to a reset signal line RL to receive a reset signal RS. A cathode terminal of the photosensitive element PD is electrically connected to the control terminal of the second transistor T2 and the second terminal of the third transistor T3. An anode terminal of the photosensitive element PD is electrically connected to a bias voltage Vbias. The photosensitive element PD may be a photodiode. A first terminal of the capacitor C is electrically connected to the control terminal of the second transistor T2 and the second terminal of the third transistor T3. A second terminal of the capacitor C is electrically connected to the bias voltage Vbias. The capacitor C may include a photodiode capacitance.

In the embodiment of the disclosure, the first transistor T1, the second transistor T2, and the third transistor T3 may be N-type transistors. The first terminal of the above transistor may be a drain terminal. The second terminal of the above transistor may be a source terminal. The control terminal of the above transistor may be a gate terminal. The third terminal of the above transistor may be another gate terminal. In the embodiment of the disclosure, when the second transistor T2 is operated in a saturation mode, there is a voltage difference existing between the first terminal (i.e. drain terminal) of the second transistor T2 and the second terminal (i.e. source terminal) of the second transistor T2, and the voltage of the first terminal (i.e. drain terminal) of the second transistor T2 is higher than the voltage of the second terminal (i.e. source terminal) of the second transistor T2, so that the first voltage VDD and the second voltage Vs are different, and the first voltage VDD is higher than the second voltage Vs (i.e., VDD>Vs).

Moreover, referring to FIG. 2A, because the second transistor T2 is operated in the saturation mode and the second transistor T2 is the N-type transistor, a threshold voltage of the second transistor T2 is positive, the second voltage Vs of the second terminal and the third terminal of the second transistor T2 are lower than a voltage of the control terminal (i.e. gate terminal) of the second transistor T2, and the first voltage VDD of the first terminal of the second transistor T2 is higher than a voltage of the control terminal of the second transistor T2 (i.e., voltage of the node BE) minus the threshold voltage of the second transistor T2. That is, when the second transistor T2 is operated in the saturation mode, an electric field is generated between the control terminal (i.e. gate terminal) and the third terminal (i.e. another gate terminal) of the second transistor T2 because the voltage of the control terminal (i.e. gate terminal) of the second transistor T2 is higher than the second voltage Vs of the third terminal of the second transistor T2. Therefore, since a direction of the electric field between the control terminal (i.e. gate terminal) of the second transistor T2 and the third terminal (i.e. another gate terminal) of the second transistor T2 is perpendicular to a direction of the current from the first terminal of the second transistor T2 to the second terminal of the second transistor T2, therefore the kink effect of the second transistor T2 can be effectively improved.

FIG. 2B is a timing diagram of the sensing pixel 200 according to an embodiment of the disclosure. Referring to FIG. 2A and FIG. 2B, in the embodiment of the disclosure, during a reset period Pr from time to t0 time t1, the first transistor T1 may be turned-off by the read control signal RDS with a low voltage level, and the third transistor T3 may be turned-on by the reset signal RS with a high voltage level. Thus, a voltage of the cathode terminal of the photosensitive element PD (i.e., voltage of the node BE) is reset to the reset voltage Vrst. Then, during an exposure period Pe from time t1 to time t2, the first transistor T1 may be turned-off by the read control signal RDS with the low voltage level, and the third transistor T3 may be turned-off by the reset signal RS with the low voltage level. The photosensitive element PD may be operated to perform an exposure operation, and the photosensitive element PD may provide a photo-current to the node BE to generate a voltage drop ΔV_{BE} at the node BE according to the sensing result of the photosensitive element PD. Therefore, the voltage of the node BE may decrease from the reset voltage Vrst to the voltage of the reset voltage Vrst minus the voltage drop ΔV_{BE} (i.e. =Vrst-ΔV_{BE}).

Then, during a scan period Ps (or a data read-out period) from time t2 to time t3, the first transistor T1 may be turned-on by the read control signal RDS with the high voltage level, and the third transistor T3 may be turned-off by the reset signal RS with the low voltage level. A constant current Ics from the current source circuit CS flows through the second transistor T2 and the first transistor T1 through the data line DAL. Thus, due to a voltage between the drain terminal of the second transistor T2 and the source terminal of the second transistor T2 (i.e. equal to the voltage of the first voltage VDD minus the second voltage Vs) is higher than a voltage of between the gate terminal of the second transistor T2 and the source terminal of the second transistor T2 minus a threshold voltage of the second transistor T2 (i.e. equal to the voltage of node BE minus the second voltage Vs and minus the threshold voltage (Vth)), the second transistor T2 is operated in the saturation mode. From theoretical transistor formula for the saturation mode, the voltage of the second terminal of the second transistor T2 is the voltage of the control terminal of the second transistor T2 (i.e. the voltage of node BE) minus the threshold voltage (Vth) of the second transistor T2 minus a voltage

$$\sqrt{\frac{2 \times I c s \times L}{W \times μ \times Cox}} ( i . e . = Vrst - Δ {V}_{B {E}^{-}} {V}_{th} - \sqrt{\frac{2 \times I c s \times L}{W \times μ \times Cox}} ) ,$$

where Ics is a constant current value, L is a length value of the second transistor T2, W is a width value of the second transistor T2, u is a mobility parameter of the second transistor T2, Cox is a gate insulator capacitance per unit area of the second transistor T2. In this regard, a voltage of the first terminal of the second transistor T2 is higher than a voltage of the voltage of the control terminal of the second transistor T2 minus the threshold voltage of the second transistor T2, and the voltage of the control terminal of the second transistor T2 is higher than a voltage of the second terminal of the second transistor T2. In other words, the second voltage Vs of the second terminal of the second transistor T2 is lower than the voltage of the control terminal of the second transistor T2 (i.e. the voltage of node BE) minus the threshold voltage (Vth) of the second transistor T2 (i.e. Vrst-ΔV_{BE}-Vth), so the second voltage Vs is lower than the voltage of the control terminal of the second transistor T2. Therefore, the second transistor T2 may be operated as a source follower amplifier to read-out a sensing result of the photosensitive element PD to output the corresponding data signal DAS with the second voltage Vs of the second terminal of the second transistor T2

$$( i . e . = Vrst - Δ {V}_{B E} - {V}_{th} - \sqrt{\frac{2 \times I c s \times L}{W \times μ \times Cox}} ) .$$

The parameters in the equation have the same or similar definitions as mentioned above.

However, in one embodiment of the disclosure, the first transistor T1, the second transistor T2, and the third transistor T3 may be P-type transistors. When the second transistor T2 is a P-type transistor, the first terminal of the second transistor T2 may be a source terminal electrically connected the second voltage Vs, and the second terminal of the second transistor T2 may be a drain terminal electrically connected to a third voltage (e.g. voltage VSS). In the embodiment of the disclosure, when the second transistor T2 is the P-type transistor and is operated in a saturation mode, there is a voltage difference existing between the first terminal (i.e. source terminal) of the second transistor T2 and the second terminal (i.e. drain terminal) of the second transistor T2, and the voltage of the first terminal (i.e. source terminal) of the second transistor T2 is higher than the voltage of the second terminal (i.e. drain terminal) of the second transistor T2, so that the second voltage Vs is higher than the third voltage VSS (i.e., Vs>VSS).

FIG. 3 is a structural cross-sectional view of a transistor according to an embodiment of the disclosure. Referring to FIG. 2A and FIG. 3, the structure of the second transistor T2 may be implemented as the structure of the transistor structure 300. The transistor structure 300 is a double-gate transistor structure. In the embodiment of the disclosure, the transistor structure 300 includes a substrate 370, a buffer layer 310, a first insulation layer 320, a semiconductor layer 330, a second insulation layer 340, and a third insulation layer 350. The sensing pixel (e.g. the sensing pixel 200 of FIG. 2A) is disposed on the substrate 370. The second transistor T2 of the sensing pixel includes a first gate electrode 364, the semiconductor layer 330, the first insulation layer 320, a second gate electrode 361, and the second insulation layer 340.

In the embodiment of the disclosure, the first gate electrode 364 is disposed on the buffer layer 310. The first insulation layer 320 covers the first gate electrode 364. The semiconductor layer 330 is disposed on the first insulation layer 320. The second insulation layer 340 is disposed on the semiconductor layer 330. The second transistor T2 of the sensing pixel further includes a connection electrode 351, an electrode 362, and an electrode 363. The second gate electrode 361 and a connection electrode 351 are disposed on the second insulation layer 340. The third insulation layer 350 covers the second gate electrode 361. The electrode 362 and the electrode 363 are disposed on the third insulation layer 350.

The electrode 362 is electrically connected to the connection electrode 351 through a through hole 301 disposed in the third insulation layer 350, and the connection electrode 351 is electrically connected to the first gate electrode 364 through a through hole 302 disposed in the first insulation layer 320, the semiconductor layer 330, and the second insulation layer 340. The electrode 362 is further electrically connected to the semiconductor layer 330 through a through hole 303 disposed in the second insulation layer 340 and the third insulation layer 350. The electrode 363 is further electrically connected to the semiconductor layer 330 through a through hole 304 formed in the second insulation layer 340 and the third insulation layer 350. It should be noted that, in top view, a projection of the first gate electrode 364 on the substrate 370 overlaps with a projection of the second gate electrode 361 on the substrate 370.

In the embodiment of the disclosure, the first terminal (i.e. drain terminal) of the second transistor T2 is electrically connected to the electrode 363. The second terminal (i.e. source terminal) and the third terminal (i.e. another gate terminal) of the second transistor T2 is electrically connected to the electrode 362, so that the third terminal (i.e. another gate terminal) of the second transistor T2 is electrically connected to the second terminal (i.e. source terminal) of the second transistor T2 through the electrode 362 to receive the second voltage Vs of the second terminal (i.e. source terminal) of the second transistor T2. The control terminal (i.e. gate terminal) of the second transistor T2 is electrically connected to the second gate electrode 361.

In the embodiment of the disclosure, when the second transistor T2 is operated in a saturation mode, a voltage difference is formed between the electrode 362 and the electrode 363, so that a current channel 331 is formed in the semiconductor layer 330 for providing a current path between the electrode 362 and the electrode 363. That is, a current flows from the first terminal of the second transistor T2 to the second terminal of the second transistor T2. Since the current flows from the first terminal of the second transistor T2 to the second terminal of the second transistor T2, a transverse electric field Eh (along the direction D1) is generated accordingly, and the transverse electric field Eh may increase with the impact ionization phenomena in the current channel 331, thereby correspondingly changing and increasing the current flows from the first terminal of the second transistor T2 to the second terminal of the second transistor T2 to cause the data signal DAS distortion (i.e. Kink effect).

Therefore, the second transistor T2 of the embodiment utilizes the first gate electrode 364 and the second gate electrode 361 to generate a vertical electric field Ev (along the direction D2) to improve Kink effect. Specifically, due to the first gate electrode 364 receives the second voltage Vs, a voltage difference is formed between the second gate electrode 361 and the first gate electrode 364, and the vertical electric field Ev is formed between the first gate electrode 364 and the second gate electrode 361. That is, the vertical electric field Ev can shield a part of the transverse electric field Eh in the current channel 331 to effectively disperse the part of the transverse electric field Eh in the current channel 331. In other words, a generation rate of impact ionization in the current channel 331 can be reduced effectively. Accordingly, the kink effect of the second transistor T2 can be effectively improved, as shown in FIG. 4.

FIG. 4 is a schematic diagram of current-voltage (I-V) characteristics of a transistor according to an embodiment of the disclosure. Referring to FIG. 4, each of the current-voltage (I-V) curves 401 to 403 of the transistor correspond to a linear region and a saturation region, and the linear region and the saturation region is divided by the dotted line 400. Curve 403 corresponds to the transistor with a higher Vgs, and curve 401 corresponds to the transistor with a lower Vgs. In a lower Vds situation and in the linear region, the Ids of the transistor T2 increase linearly according to increase of Vds. Although, when Vds is gradually increased further, the increase of Ids of the transistor T2 becomes smaller and the increase gradually saturates (saturation region). When the impact ionization phenomenon in the current channel with the transverse electric field is not improved, the increase of Ids of the transistor T2 cannot saturate enough even in the saturation region, and the Ids of the transistor T2 can increase continues according to Vds increase (i.e. kink effect). According some embodiments, in the saturation region, the Ids of the transistor T2 maintains almost constant when Vds increases. That is to say, the Ids of the transistor T2 will not vary in a great extent when Vds increases. Thus, the kink effect can be improved. For any voltage Vgs (i.e. voltage between the gate terminal and the source terminal) of the second transistor T2, in the saturation region, as the voltage Vds (i.e. voltage between the drain terminal and the source terminal) of the second transistor T2 rises, the second transistor T2 can output a stable current Ids (i.e. the current flows from the drain terminal to the source terminal of the second transistor T2).

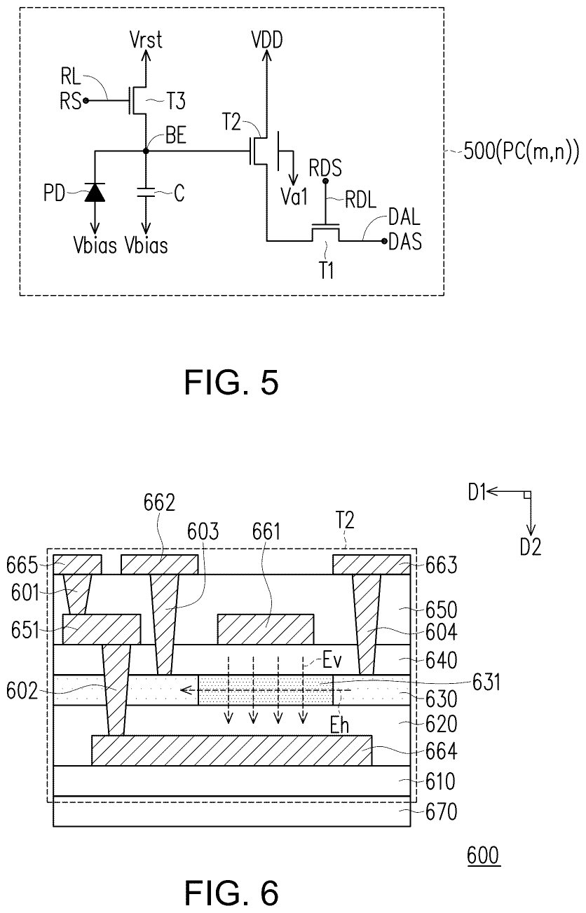

FIG. 5 is a schematic diagram of a sensing pixel according to another embodiment of the disclosure Referring to FIG. 5, the circuit architecture of each of the sensing pixels PC(1,1) to PC(m,n) of FIG. 1 may be implemented as the circuit architecture of a sensing pixel 500 of FIG. 5. In the embodiment of the disclosure, the sensing pixel 500 includes a photosensitive element PD, a capacitor C, a first transistor T1, a second transistor T2, and a third transistor T3. The first transistor T1 includes a first terminal, a second terminal, and a control terminal. The control terminal of the first transistor T1 is electrically connected to a read signal line RDL to receive a read control signal RDS. The first terminal of the first transistor T1 is electrically connected to the second transistor T2. The second terminal of the first transistor T1 is electrically connected to data line DAL to output a data signal DAS. The second transistor T2 includes a first terminal, a second terminal, a third terminal, and a control terminal. The control terminal of the second transistor T2 is electrically connected to the photosensitive element PD. The first terminal of the second transistor T2 is electrically connected to a first voltage VDD. The second terminal of the second transistor T2 is electrically connected to the first terminal of the first transistor T1. The third terminal of the second transistor T2 is electrically connected to a fixed voltage Va1. The third transistor T3 includes a first terminal, a second terminal, and a control terminal. The first terminal of the third transistor T3 is electrically connected to a reset voltage Vrst. The second terminal of the third transistor T3 is electrically connected to the photosensitive element PD. The control terminal of the third transistor T3 is electrically connected to a reset signal line RL to receive a reset signal RS. A cathode terminal of the photosensitive element PD is electrically connected to the control terminal of the second transistor T2 and the second terminal of the third transistor T3. An anode terminal of the photosensitive element PD is electrically connected to a bias voltage Vbias. The photosensitive element PD may be a photodiode. A first terminal of the capacitor C is electrically connected to the control terminal of the second transistor T2 and the second terminal of the third transistor T3. A second terminal of the capacitor C is electrically connected to the bias voltage Vbias. The capacitor C may include a photodiode capacitance.

In the embodiment of the disclosure, the first transistor T1, the second transistor T2, and the third transistor T3 may be N-type transistors. The first terminal of the above transistor may be a drain terminal. The second terminal of the above transistor may be a source terminal. The control terminal of the above transistor may be a gate terminal. The third terminal of the above transistor may be another gate terminal. In the embodiment of the disclosure, when the second transistor T2 is operated in a saturation mode, there is a voltage difference existing between the first terminal (i.e. drain terminal) of the second transistor T2 and the second terminal (i.e. source terminal) of the second transistor T2, and the voltage of the first terminal (i.e. drain terminal) of the second transistor T2 is higher than the voltage of the second terminal (i.e. source terminal) of the second transistor T2. In the embodiment of the disclosure, the fixed voltage Va1 may be designed to be lower than a voltage of the control terminal of the second transistor T2 and the first voltage VDD. That is, the first voltage VDD is higher than the fixed voltage Va1 (i.e., VDD>Va1). However, in one embodiment of the disclosure, the first transistor T1, the second transistor T2, and the third transistor T3 may be P-type transistors.

Moreover, referring to FIG. 5, because the second transistor T2 is operated in the saturation mode and the second transistor T2 is the N-type transistor, a threshold voltage of the second transistor T2 is positive, the second terminal (i.e. source terminal) and the third terminal (i.e. the fixed voltage Va1) of the second transistor T2 are lower than a voltage of the control terminal (i.e. gate terminal) of the second transistor T2, and the first voltage VDD of the first terminal of the second transistor T2 is higher than a voltage of a voltage of the control terminal of the second transistor T2 (i.e. voltage of the node BE) minus the threshold voltage of the second transistor T2. That is, when the second transistor T2 operating in the saturation mode, an electric field is generated between the control terminal (i.e. gate terminal) and the third terminal (i.e. another gate terminal) of the second transistor T2 because the voltage of the control terminal (i.e. gate terminal) of the second transistor T2 is higher than the fixed voltage Va1 of the third terminal of the second transistor T2. Therefore, since a direction of the electric field between the control terminal (i.e. gate terminal) of the second transistor T2 and the third terminal (i.e. another gate terminal) of the second transistor T2 is perpendicular to a direction of the current from the first terminal of the second transistor T2 to the second terminal of the second transistor T2, therefore the kink effect of the second transistor T2 can be effectively improved.

In the embodiment of the disclosure, the sensing pixel 500 may also be operated according to the timing diagram of FIG. 2B. Therefore, during the scan period Ps (or a data read-out period) from time t2 to time t3, the second transistor T2 may be operated as a source follower amplifier to read-out a sensing result of the photosensitive element PD to output the corresponding data signal DAS with the voltage of the second terminal of the second transistor T2 minus a voltage

$$( i . e . = Vrst - Δ {V}_{B {E}^{-}} {V}_{th} - \sqrt{\frac{2 \times I c s \times L}{W \times μ \times Cox}} ) .$$

The parameters in the equation have the same or similar definitions as mentioned above.

FIG. 6 is a structural cross-sectional view of a transistor according to an embodiment of the disclosure. Referring to FIG. 5 and FIG. 6, the semiconductor structure of the second transistor T2 may be implemented as the semiconductor structure of the transistor structure 600. The transistor structure 600 is a double-gate transistor structure. In the embodiment of the disclosure, the transistor structure 600 includes a substrate 670, a buffer layer 610, a first insulation layer 620, a semiconductor layer 630, a second insulation layer 640, and a third insulation layer 650. The sensing pixel (e.g. the sensing pixel 500 of FIG. 5) is disposed on the substrate 670. The second transistor T2 of the sensing pixel includes a first gate electrode 664, the semiconductor layer 630, the first insulation layer 620, a second gate electrode 661, and the second insulation layer 640.

In the embodiment of the disclosure, the first gate electrode 664 is disposed on the buffer layer 610. The first insulation layer 620 covers the first gate electrode 664. The semiconductor layer 630 is disposed on the first insulation layer 620. The second insulation layer 640 is disposed on the semiconductor layer 630. The second transistor T2 of the sensing pixel further includes a connection electrode 651, an electrode 662, an electrode 663, and an electrode 665. The second gate electrode 661 and the connection electrode 651 are disposed on the second insulation layer 640. The third insulation layer 650 covers the second gate electrode 661. The electrode 662, the electrode 663, and the electrode 665 are disposed on the third insulation layer 650.

Referring to FIG. 6, the electrode 665 is electrically connected to the connection electrode 651 through a through hole 601 disposed in the third insulation layer 650, and the connection electrode 651 is electrically connected to the first gate electrode 664 through a through hole 602 disposed in the first insulation layer 620, the semiconductor layer 630, and the second insulation layer 640, such that the fixed voltage Va1 at the electrode 665 can be provided to the first gate electrode 664. The electrode 662 is electrically connected to the semiconductor layer 630 through a through hole 603 disposed in the second insulation layer 640 and the third insulation layer 650. The electrode 663 is further electrically connected to the semiconductor layer 630 through a through hole 604 disposed in the second insulation layer 640 and the third insulation layer 650. It should be noted that, in top view, a projection of the first gate electrode 664 on the substrate 670 overlaps with a projection of the second gate electrode 661 on the substrate 670.

In the embodiment of the disclosure, the first terminal (i.e. drain terminal) of the second transistor T2 is electrically connected to the electrode 663. The second terminal (i.e. source terminal) of the second transistor T2 is electrically connected to the electrode 662. The third terminal (i.e. another gate terminal) of the second transistor T2 is electrically connected to the electrode 665 to receive the fixed voltage Va1. The control terminal (i.e. gate terminal) of the second transistor T2 is electrically connected to the second gate electrode 661.

In the embodiment of the disclosure, when the second transistor T2 is operated in a saturation mode, a voltage difference is formed between the electrode 662 and the electrode 663, so that a current channel 631 is formed in the semiconductor layer 630 for providing a current path between the electrode 662 and the electrode 663. That is, a current flows from the first terminal of the second transistor T2 to the second terminal of the second transistor T2. Since the current flows from the first terminal of the second transistor T2 to the second terminal of the second transistor T2, a transverse electric field Eh (along the direction D1) is generated accordingly, and the transverse electric field Eh may increase with the impact ionization phenomena in the current channel 631, thereby correspondingly changing and increasing the current flows from the first terminal of the second transistor T2 to the second terminal of the second transistor T2 (i.e. Kink effect).

Therefore, the second transistor T2 of the embodiment utilizes the first gate electrode 664 and the second gate electrode 661 to generate a vertical electric field Ev (along the direction D2) to improve Kink effect. Specifically, due to the first gate electrode 664 receives the fixed voltage Va1 from the electrode 665, a voltage difference is formed between the second gate electrode 661 and the first gate electrode 664, the vertical electric field Ev is formed between the first gate electrode 664 and the second gate electrode 661. That is, the vertical electric field Ev can shield a part of the transverse electric field Eh in the current channel 631 to effectively disperse the part of the transverse electric field Eh in the current channel 631. In other words, a generation rate of impact ionization in the current channel 631 can be reduced effectively. Accordingly, the kink effect of the second transistor T2 can be effectively improved, as shown in FIG. 4.

Therefore, as shown as FIG. 4, in the case of improving the kink effect, for any voltage Vgs (i.e. voltage between the gate terminal and the source terminal) of the second transistor T2, as the voltage Vds (i.e. voltage between the drain terminal and the source terminal) of the second transistor T2 rises, the second transistor T2 can output a stable current Ids (i.e. the current flows from the drain terminal to the source terminal of the second transistor T2).

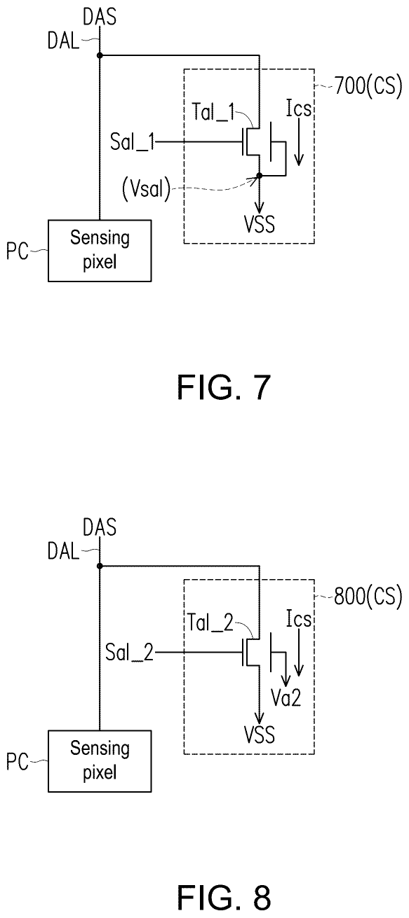

FIG. 7 is a schematic diagram of a current source circuit according to an embodiment of the disclosure. Referring to FIG. 7, the circuit architecture of each of the current source circuits CS_1 to CS_n of FIG. 1 may be implemented as the circuit architecture of a current source circuit 700 of FIG. 7. In the embodiment of the disclosure, the current source circuit 700 includes an active load transistor Tal_1. The active load transistor Tal_1 includes a first terminal, a second terminal, a third terminal, and a control terminal. The first terminal of the active load transistor Tal_1 is electrically connected to a sensing pixel PC(e.g. one column of the sensing pixels PC(1,1) to PC(m,n) of FIG. 1) through a data line DAL. The second terminal of the active load transistor Tal_1 is electrically connected to a third voltage VSS (i.e. operation voltage). The third terminal of the active load transistor Tal_1 is electrically connected to the second terminal of the active load transistor Tal_1 to receive a fourth voltage Vsa1 (i.e. voltage of the second terminal of the active load transistor Tal_1). That is, the fourth voltage Vsa1 is equal to the third voltage VSS. The control terminal of the active load transistor Tal_1 receives an active load control signal Sal_1.

In the embodiment of the disclosure, the active load transistor Tal_1 may be an N-type transistor. The first terminal of the active load transistor Tal_1 may be a drain terminal. The second terminal of the active load transistor Tal_1 may be a source terminal. The control terminal of the active load transistor Tal_1 may be a gate terminal. The third terminal of the active load transistor may be another gate terminal. However, in one embodiment of the disclosure, the active load transistor Tal_1 may be a P-type transistor.

Specifically, in the embodiment of the disclosure, during a data read-out period of the sensing pixel PC, the active load transistor Tal_1 may be operated in a saturation mode according to the active load control signal Sal_1 with a high voltage level, so that a constant current Ics (i.e. the current Ids flows from the first terminal to the second terminal of the active load transistor Tal_1) is formed between the first terminal of the active load transistor Tal_1 and the second terminal of the active load transistor Tal_1. The constant current Ics flows from the first terminal of the active load transistor Tal_1 to the second terminal of the active load transistor Tal_1. Therefore, a data signal DAS of the sensing result of the sensing pixel PC may be effectively read-out from the data signal line DAL to the corresponding amplifier circuit. The first terminal of the active load transistor Tal_1 is electrically connected to the data line DAL to receive the data signal DAS. Moreover, when the active load transistor Tal_1 is operated in the saturation mode and the active load transistor Tal_1 is the N-type transistor, a threshold voltage of the active load transistor Tal_1 is positive, the fourth voltage Vsa1 is lower than a voltage of the control terminal of the active load transistor Tal_1, and a voltage of the data signal DAS of the first terminal of the active load transistor Tal_1 is higher than a voltage of the control terminal of the active load transistor Tal_1 minus the threshold voltage of the active load transistor Tal_1.

In the embodiment of the disclosure, the semiconductor structure of the active load transistor Tal_1 may also be implemented as the semiconductor structure of the transistor structure 300 of FIG. 3. Therefore, the kink effect of the active load transistor Tal_1 can be effectively improved as shown as FIG. 4. The current-voltage (I-V) characteristics 401 to 403 of FIG. 4 may also be adapted to the active load transistor Tal_1 of the current source circuit 700 of FIG. 7. As shown in FIG. 4, in the case of improving the kink effect, for any voltage Vgs (i.e. voltage between the gate terminal and the source terminal) of the active load transistor Tal_1, as the voltage Vds (i.e. voltage between the drain terminal and the source terminal) of the active load transistor Tal_1 rises, the active load transistor Tal_1 can output the stable constant current Ics (i.e. the current Ids flows from the drain terminal to the source terminal of the active load transistor Tal_1), so as to effectively stable the operation of the active load transistor Tal_1 as a source follower amplifier, and effectively stable the data signal DAS transmitted on the data line DAL.

FIG. 8 is a schematic diagram of a current source circuit according to another embodiment of the disclosure. Referring to FIG. 8, the circuit architecture of each of the current source circuits CS_1 to CS_n of FIG. 1 may be implemented as the circuit architecture of a current source circuit 800 of FIG. 8. In the embodiment of the disclosure, the current source circuit 800 includes an active load transistor Tal_2. The active load transistor Tal_2 includes a first terminal, a second terminal, a third terminal, and a control terminal. The first terminal of the active load transistor Tal_2 is electrically connected to a sensing pixel PC(e.g. one column of the sensing pixels PC(1,1) to PC(m,n) of FIG. 1) through a data line DAL. The second terminal of the active load transistor Tal_2 is electrically connected to a third voltage VSS. The third terminal of the active load transistor Tal_2 is electrically connected to a fixed voltage Va2 such that the fixed voltage Va2 can be provided to a first gate electrode (e.g., the gate electrode has the same function as the first gate electrode 364 or 664) of the active load transistor Tal_2. The control terminal of the active load transistor Tal_2 receives an active load control signal Sal_2.

In the embodiment of the disclosure, the active load transistor Tal_2 may be an N-type transistor. The first terminal of the active load transistor Tal_2 may be a drain terminal. The second terminal of the active load transistor Tal_2 may be a source terminal. The control terminal of the active load transistor Tal_2 may be a gate terminal. The third terminal of the active load transistor may be another gate terminal. In the embodiment of the disclosure, when the active load transistor Tal_2 is operated in the saturation mode, there is a voltage difference existing between the first terminal (i.e. drain terminal) of the active load transistor Tal_2 and the second terminal (i.e. source terminal) of the active load transistor Tal_2, and the voltage of the first terminal (i.e. drain terminal) of the active load transistor Tal_2 is higher than the voltage of the second terminal (i.e. source terminal) of the active load transistor Tal_2. In the embodiment of the disclosure, the fixed voltage Va2 may be designed to be equal to or different from the third voltage VSS, and the fixed voltage Va2 may be designed to be lower than a voltage of the control terminal of the active load transistor Tal_2 and the first voltage VDD. That is, the fixed voltage Va2 may be equal to or different from the third voltage VSS, and lower than a voltage of the control terminal of the active load transistor Tal_2. However, in one embodiment of the disclosure, the active load transistor Tal_2 may be a P-type transistor.

Moreover, when the active load transistor Tal_2 is operated in the saturation mode, an electric field is generated between the control terminal (i.e. gate terminal) and the third terminal (i.e. another gate terminal) of the active load transistor Tal_2 because the voltage of the control terminal (i.e. gate terminal) of the active load transistor Tal_2 is higher than the fixed voltage Va2 of the third terminal of the active load transistor Tal_2. Therefore, since a direction of the electric field between the control terminal (i.e. gate terminal) of the active load transistor Tal_2 and the third terminal (i.e. another gate terminal) of the active load transistor Tal_2 is perpendicular to a direction of the current from the first terminal of the active load transistor Tal_2 to the second terminal of the active load transistor Tal_2, therefore the kink effect of the active load transistor Tal_2 can be effectively improved.

Specifically, in the embodiment of the disclosure, during a data read-out period of the sensing pixel PC, the active load transistor Tal_2 may be operated in a saturation mode according to the active load control signal Sal_2 with a high voltage level, so that a constant current Ics (i.e. the current Ids flows from the first terminal to the second terminal of the active load transistor Tal_2) is formed between the first terminal of the active load transistor Tal_2 and the second terminal of the active load transistor Tal_2. The constant current Ics flows from the first terminal of the active load transistor Tal_2 to the second terminal of the active load transistor Tal_2. Therefore, a data signal DAS of the sensing result of the sensing pixel PC may be effectively read-out from the data signal line DAL to the corresponding amplifier circuit.

In the embodiment of the disclosure, the semiconductor structure of the active load transistor Tal_2 may also be implemented as the semiconductor structure of the transistor structure 600 of FIG. 6. Therefore, the kink effect of the active load transistor Tal_2 can be effectively improved as shown as FIG. 4. The current-voltage (I-V) characteristics 401 to 403 of FIG. 4 may also be adapted to the active load transistor Tal_2 of the current source circuit 800 of FIG. 8. As shown in FIG. 4, in the case of improving the kink effect, for any voltage Vgs (i.e. voltage between the gate terminal and the source terminal) of the active load transistor Tal_2, as the voltage Vds (i.e. voltage between the drain terminal and the source terminal) of the active load transistor Tal_2 rises, the active load transistor Tal_2 can output the stable constant current Ics (i.e. the current Ids flows from the drain terminal to the source terminal of the active load transistor Tal_2), so as to effectively stable the operation of the active load transistor Tal_2 as a source follower amplifier, and effectively stable the data signal DAS transmitted on the data line DAL.

It should be noted that, referring to FIG. 1, in one embodiment of the disclosure, at least one of the sensing pixels PC(1,1) to PC(m,n) of the pixel array 110 of the electronic device 100 may be implemented as the sensing pixel 200 of FIG. 2A or the sensing pixel 500 of FIG. 5, and at least one of the current source circuits CS_1 to CS_n of the peripheral circuit 120 of the electronic device 100 is not necessarily implemented as the current source circuit 700 of FIG. 7 or the current source circuit 800 of FIG. 8. The at least one of the current source circuits CS_1 to CS_n of the peripheral circuit 120 of the electronic device 100 may be implemented as a general current source circuit. In another one embodiment of the disclosure, at least one of the sensing pixels PC(1,1) to PC(m,n) of the pixel array 110 of the electronic device 100 may be implemented as the sensing pixel 200 of FIG. 2A or the sensing pixel 500 of FIG. 5, and at least one of the current source circuits CS_1 to CS_n of the peripheral circuit 120 of the electronic device 100 may be implemented as the current source circuit 700 of FIG. 7 or the current source circuit 800 of FIG. 8. In yet one embodiment of the disclosure, at least one of the current source circuits CS_1 to CS_n of the peripheral circuit 120 of the electronic device 100 may be implemented as the current source circuit 700 of FIG. 7 or the current source circuit 800 of FIG. 8, and at least one of the sensing pixels PC(1,1) to PC(m,n) of the pixel array 110 of the electronic device 100 is not necessarily implemented as the sensing pixel 200 of FIG. 2A or the sensing pixel 500 of FIG. 5. The at least one of the sensing pixels PC(1,1) to PC(m,n) of the pixel array 110 of the electronic device 100 may be implemented as a general sensing pixel.

In summary, the electronic device of the disclosure can apply the transistor with the double-gate transistor structure in the source follower amplifier in the sensing pixel or in the current source of the read-out circuit, so that the kink effect of the transistor in the source follower amplifier or in the current source of the read-out circuit can be effectively improved. Therefore, the electronic device of the disclosure can provide stable circuit operation.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. An electronic device, comprising a sensing pixel, wherein the sensing pixel comprises:
a photosensitive element;
a first transistor, comprising a first terminal, a second terminal, and a control terminal, wherein the control terminal of the first transistor is electrically connected to a read signal line, and the second terminal of the first transistor is electrically connected to a data line;
a second transistor, comprising a first terminal, a second terminal, a third terminal, and a control terminal, wherein the control terminal of the second transistor is electrically connected to the photosensitive element, the first terminal of the second transistor is electrically connected to a first voltage, the second terminal of the second transistor is electrically connected to the first terminal of the first transistor, and the third terminal of the second transistor is electrically connected to a second voltage; and
a third transistor, comprising a first terminal, a second terminal, and a control terminal, wherein the first terminal of the third transistor is electrically connected to a reset voltage, the second terminal of the third transistor is electrically connected to the photosensitive element, and the control terminal of the third transistor is electrically connected to a reset signal line.

2. The electronic device according to claim 1, wherein the second terminal of the second transistor has the second voltage, and the third terminal of the second transistor is electrically connected to the second terminal of the second transistor to receive the second voltage.

3. The electronic device according to claim 1, wherein when the second transistor is operated in a saturation mode and the second transistor is an N-type transistor, a threshold voltage of the second transistor is positive, the second voltage is lower than a voltage of the control terminal of the second transistor, and the first voltage of the first terminal of the second transistor is higher than a voltage of the control terminal of the second transistor minus the threshold voltage of the second transistor.

4. The electronic device according to claim 1, comprising:
a substrate; and
the sensing pixel, disposed on the substrate,
wherein the second transistor of the sensing pixel comprises:
a first gate electrode, electrically connected to the third terminal of the second transistor;
a semiconductor layer;
a first insulation layer, disposed between the first gate electrode and the semiconductor layer;
a second gate electrode, electrically connected to the control terminal of the second transistor; and
a second insulation layer, disposed between the second gate electrode and the semiconductor layer, wherein a projection of the first gate electrode on the substrate overlaps with a projection of the second gate electrode on the substrate.

5. The electronic device according to claim 4, wherein when the second transistor is operated in a saturation mode, a vertical electric field is formed between the first gate electrode and the second gate electrode.

6. The electronic device according to claim 1, wherein the second voltage is a fixed voltage.

7. The electronic device according to claim 1, wherein the first voltage and the second voltage are different.

8. The electronic device according to claim 1, wherein the second transistor is an N-type transistor, and the first voltage is higher than the second voltage.

9. The electronic device according to claim 1, wherein the second transistor is a P-type transistor, and the first voltage is lower than the second voltage.

10. The electronic device according to claim 1, further comprising a current source circuit, wherein the current source circuit comprises:
an active load transistor, comprising a first terminal, a second terminal, and a third terminal, and a control terminal, wherein the first terminal of the active load transistor is electrically connected to the sensing pixel through a data line, the second terminal of the active load transistor is electrically connected to a third voltage, the third terminal of the active load transistor is electrically connected to a fourth voltage, the control terminal of the active load transistor is electrically connected to an active load control signal.

11. The electronic device according to claim 10, wherein the third terminal of the active load transistor is electrically connected to the second terminal of the active load transistor.

12. The electronic device according to claim 10, wherein the fourth voltage is a fixed voltage.

13. The electronic device according to claim 10, wherein the third voltage is equal to the fourth voltage.

14. The electronic device according to claim 10, comprising
a substrate;
the sensing pixel disposed on the substrate; and
the current source circuit disposed on the substrate.

15. The electronic device according to claim 14,
wherein the substrate comprises an active area and a peripheral area, and
wherein the sensing pixel is disposed in the active area of the substrate, and the current source circuit is disposed in the peripheral area of the substrate.

16. An electronic device, comprising a current source circuit, wherein the current source circuit comprises:
an active load transistor, comprising a first terminal, a second terminal, and a third terminal, and a control terminal, wherein the first terminal of the active load transistor is electrically connected to a sensing pixel through a data line, the second terminal of the active load transistor is electrically connected to a third voltage, the third terminal of the active load transistor is electrically connected to a fourth voltage, the control terminal of the active load transistor is electrically connected to an active load control signal.

17. The electronic device according to claim 16, wherein the third terminal of the active load transistor is electrically connected to the second terminal of the active load transistor.

18. The electronic device according to claim 16, wherein when the active load transistor is operated in a saturation mode and the active load transistor is an N-type transistor, a threshold voltage of the active load transistor is positive, the fourth voltage is lower than a voltage of the control terminal of the active load transistor, and a voltage of the first terminal of the active load transistor is higher than a voltage of the control terminal of the active load transistor minus the threshold voltage of the active load transistor.

19. The electronic device according to claim 16, wherein the fourth voltage is a fixed voltage.

20. The electronic device according to claim 16, wherein the third voltage is equal to the fourth voltage.
